(19) United States
(12) Patent Application Publication
(10) Pub. No.: US 2012/0325309 A1
(43) Pub. Date: Dec. 27, 2012

(54) SOLAR CELL AND SOLAR CELL MANUFACTURING METHOD

(75) Inventors: Tsuyoshi TAKAHAMA, Neyagawa-shi (JP); Hiroyuki MORI, Kaizuka-shi (JP); Tomohiro SAITOU, Sakai-shi (JP); Youhei MURAKAMI, Izumisano-shi (JP)

(73) Assignee: SANYO ELECTRIC CO., LTD., Moriguchi-shi (JP)

(21) Appl. No.: 13/559,777

(22) Filed: Jul. 27, 2012

Related U.S. Application Data
(63) Continuation of application No. PCT/JP2011/051561, filed on Jan. 27, 2011.

(30) Foreign Application Priority Data
Jan. 28, 2010 (JP) 2010-017369

(51) Int. Cl. H01L 31/0352; H01L 31/18

(52) U.S. Cl. 136/256; 438/57; 257/E31.032

(57) ABSTRACT

[The PROBLEMS] A solar cell capable of preventing scratches from occurring on a junction portion between a semiconductor layer and a semiconductor substrate, and capable of suppressing deterioration of conversion efficiency is provided.

[MEANS FOR SOLVING] The present invention is a solar cell 1 comprising a semiconductor substrate 10 having a light receiving surface and a back surface, a first semiconductor region 20 of a first conductivity type and a second semiconductor layer 30 of a second conductivity type, both being disposed on the back surface of the semiconductor substrate, wherein the semiconductor substrate 10 includes a plurality of protruding portions 50 on the back surface, the first semiconductor region 20 is provided in a surface of each of the protruding portions 50, the second semiconductor layer 30 is provided on the semiconductor substrate 10 located between one protruding portion 50a and another protruding portion 50b adjacent to the one protruding portion 50a, and the one protruding portion 50a and the other protruding portion 50b constitute a recessed portion 55 whose bottom portion 57 is formed by the second semiconductor layer 30.

### TECHNICAL FIELD

The present invention relates to a back contact type solar cell including an n-type semiconductor region and a p-type semiconductor region disposed on a back surface of a semiconductor substrate.

### BACKGROUND ART

Solar cells are expected to be new energy sources, because the solar cells can convert clean and abundantly supplied solar light energy into electrical energy directly.

There has conventionally been known a solar cell in which an n-type conductivity semiconductor layer and a p-type conductivity semiconductor layer are formed on a back surface of a semiconductor substrate, i.e., a back contact type solar cell. Such a solar cell is disclosed in Japanese Patent Application Publication No. Hei 11-112011, for example. On these semiconductor layers, electrodes are formed to collect photo-generated carriers generated by reception of light.

In a back contact type solar cell, since both an n-type semiconductor layer and a p-type semiconductor layer are formed on the back surface side of a semiconductor substrate, semiconductor layers and electrodes of different conductivity types are likely to come into contact with each other, or positive and negative electrodes are likely to come into contact with each other. A short circuit is caused when such a contact occurs. For this reason, there is used a method in which electrodes are formed using metal masks or a method in which unnecessary semiconductor layers and unnecessary electrode layers are removed after formation of resists by use of screen printing.

### PRIOR ART DOCUMENT

### Patent Document

Patent Document 1: Japanese Patent Application Publication No. Hei 11-112011

### SUMMARY OF THE INVENTION

### Problems to Be Solved by the Invention

When electrodes are formed or semiconductor layers are removed using the above methods, however, scratches may occur on the semiconductor layers. Specifically, when a metal mask used for electrode formation or a screen pushed by a squeegee in screen printing comes into contact with a semiconductor layer, scratches may occur on the semiconductor layer. Thin film semiconductor layers have been widely used in recent years. In the case of thin film semiconductor layers, scratches may reach semiconductor substrates. Moreover, scratches may occur not only in formation of electrodes but also in handling of solar cells. When scratches occur at a junction portion between a semiconductor layer and a semiconductor substrate, a function of the junction portion deteriorates. When the junction portion having scratches is a p-n junction, conversion efficiency may deteriorate. When a semiconductor layer serving as a passivation layer is provided, the junction portion having scratches cannot prevent recombination of carriers.

The present invention has been made in view of the above circumstances, and an objective thereof is to provide a solar cell capable of preventing scratches from occurring on a junction portion between a semiconductor layer and a semiconductor substrate, and capable of suppressing deterioration of conversion efficiency.

### Means for Solving the Problems

To solve the above-described problem, a solar cell according to the aspect of the present invention is a solar cell comprising a semiconductor substrate having a light receiving surface and a back surface, a first semiconductor region of a first conductivity type and a second semiconductor layer of a second conductivity type, both being disposed on the back surface of the semiconductor substrate, wherein the semiconductor substrate includes a plurality of protruding portions on the back surface, the first semiconductor region is provided in a surface of each of the protruding portions, the second semiconductor layer is provided on the semiconductor substrate located between one protruding portion and another protruding portion adjacent to the one protruding portion among the plurality of protruding portions, and the one protruding portion and the other protruding portion constitute a recessed portion whose bottom portion is formed by the second semiconductor layer.

In the solar cell according to the aspect of the present invention, the second semiconductor layer is formed on the semiconductor substrate located between the one protruding portion and the other protruding portion adjacent to the one protruding portion, and each protruding portion is higher than the second semiconductor layer formed on the semiconductor substrate. For this reason, a metal mask or a screen is less likely to come into contact with the second semiconductor layer formed on the semiconductor substrate located between the one protruding portion and the other protruding portion because the one protruding portion and the other protruding portion block the metal mask or the screen. The same things can be said in handling of solar cells also. For this reason, scratches can be prevented from occurring on the junction portion between the second semiconductor layer and the semiconductor substrate. Moreover, scratches hardly occur on the junction portions between the semiconductor substrate and the first semiconductor regions because the first semiconductor regions are in the same crystal state as the semiconductor substrate.

The depth of the recessed portion is preferably 0.4 μm or more.

An interval between the one protruding portion and the other protruding portion adjacent to the one protruding portion is preferably 5 mm or less.

The semiconductor substrate is preferably of the first conductivity type.

The second semiconductor layer is preferably formed on the first semiconductor region as well.

A solar cell manufacturing method for manufacturing a solar cell according to the aspect of the present invention is a solar cell manufacturing method for manufacturing a solar cell comprising a semiconductor substrate having a light receiving surface and a back surface, a first semiconductor region of a first conductivity type and a second semiconductor layer of a second conductivity type, both being disposed on the back surface of the semiconductor substrate, wherein the method comprises: a step S1 of forming the first semiconductor region of the first conductivity type on the back surface of the semiconductor substrate having the light receiving surface and the back surface; and a step S2 of forming the second semiconductor layer of the second conductivity type on the back surface, the step S1 includes a step of forming the first semiconductor region in a surface of the semiconductor substrate by heating the semiconductor substrate and introducing impurities into the semiconductor substrate, the step S2 includes: a step S21 of exposing part of the semiconductor substrate by removing the first semiconductor region at intervals; and a step S22 of forming the second semiconductor layer on the semiconductor substrate which is exposed by the removal of the first semiconductor region, the first semiconductor region is formed in at least a surface of each of a plurality of protruding portions which are not removed but remain, and the second semiconductor layer forms a bottom portion of a recessed portion formed by one protruding portion and another protruding portion adjacent to the one protruding portion among the plurality of protruding portions.

In the step S22, the second semiconductor layer is formed on the semiconductor substrate and is also formed on the first semiconductor region preferably.

### Effects of the Invention

The present invention can provide a back contact type solar cell in which deterioration of conversion efficiency is suppressed.

### BRIEF DESCRIPTION OF THE DRAWINGS

FIG. 1 is a plan view in which a solar cell 1 according to an embodiment of the present invention is viewed from a back surface side thereof.

FIG. 2 is an enlarged cross-sectional view taken along line A-A of FIG. 1.

FIG. 3 is a flowchart for explaining a method for manufacturing the solar cell 1 according to the embodiment of the present invention.

FIG. 4 is a diagram for explaining the method for manufacturing the solar cell 1 according to the embodiment of the present invention.

FIG. 5 is a diagram for explaining the method for manufacturing the solar cell 1 according to the embodiment of the present invention.

FIG. 6 is a diagram for explaining the method for manufacturing the solar cell 1 according to the embodiment of the present invention.

FIG. 7 is a diagram for explaining the method for manufacturing the solar cell 1 according to the embodiment of the present invention.

FIG. 8 is a diagram for explaining the method for manufacturing the solar cell 1 according to the embodiment of the present invention.

### MODES FOR CARRYING OUT THE INVENTION

A solar cell according to an embodiment of the present invention will be described with reference to the drawings. In the following description of the drawings, identical or similar reference numerals are assigned to identical or similar components. The drawings are schematic, thus it should be noted that the dimensions are not shown to scale. Accordingly, specific dimensions should be recognized in consideration of the following description. Also, there are inevitably included some portions of the drawings between which a dimensional relationship and/or a scale are inconsistent.

(1) Schematic Configuration of Solar Cell 1

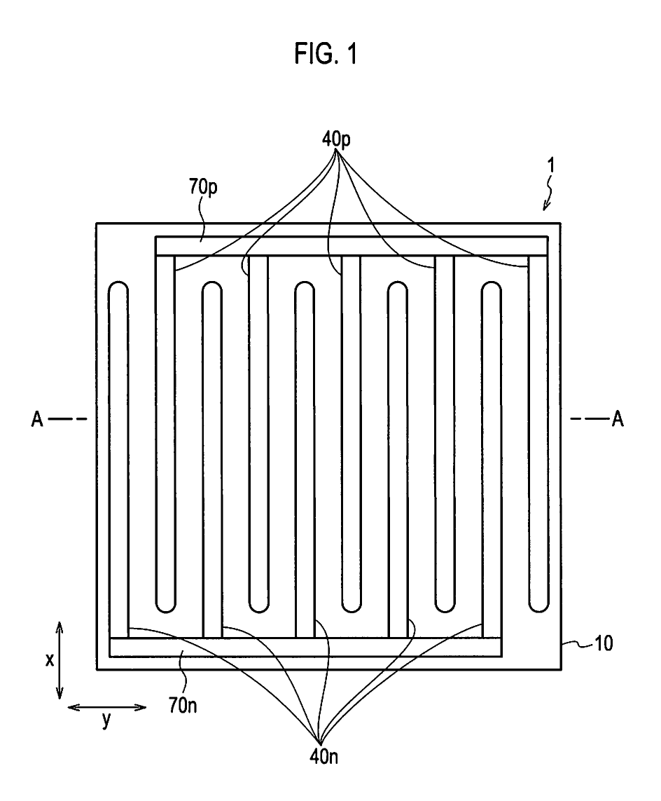

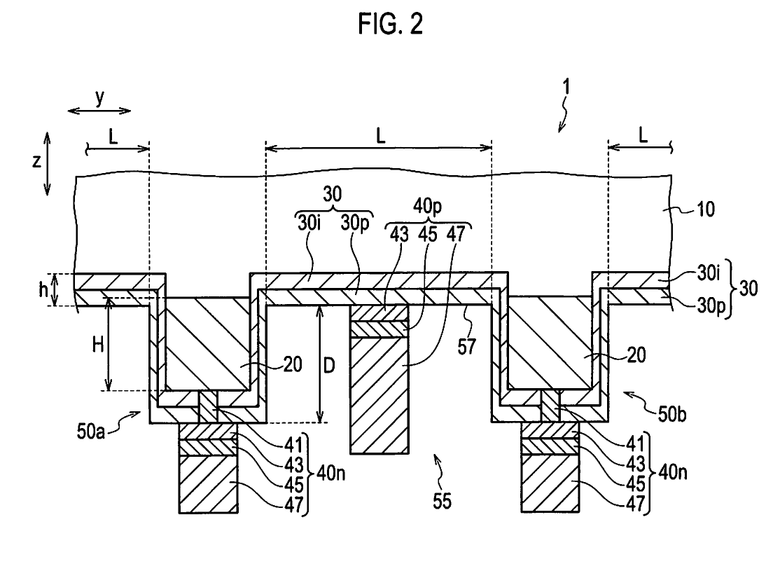

Description will be given of a schematic configuration of a solar cell 1 according to an embodiment of the present invention with reference to FIG. 1 and FIG. 2. FIG. 1 is a plan view in which the solar cell 1 according to the embodiment of the present invention is viewed from a back surface side thereof. FIG. 2 is an enlarged cross-sectional view taken along line A-A of FIG. 1.

The solar cell 1 includes a first conductivity type semiconductor substrate 10, first semiconductor regions 20, a second semiconductor layer 30, electrodes 40n, electrodes 40p, a collector electrode 70n, and a collector electrode 70p.

The semiconductor substrate 10 includes a light receiving surface which receives light, and a back surface which is provided on an opposite side to the light receiving surface. When receiving light on the light receiving surface, the semiconductor substrate 10 generates carriers (electrons and holes). In the solar cell 1 according to the embodiment, the semiconductor substrate 10 is made of n-type single-crystalline silicon. The semiconductor substrate 10 includes a plurality of protruding portions 50 (50a, 50b) on a rear side thereof.

Although unillustrated, unevenness called texture is preferably formed on the light receiving surface of the semiconductor substrate 10. This can prevent reflection of light on the light receiving surface. A passivation layer for preventing recombination of carriers is preferably provided on the light receiving surface. In addition, an antireflection film for preventing reflection of light is preferably provided on the light receiving surface. No structure (such as an electrode, for example) for blocking the entrance of light is provided on the light receiving surface of the semiconductor substrate 10, and thus the semiconductor substrate 10 can receive light on the entire light receiving surface.

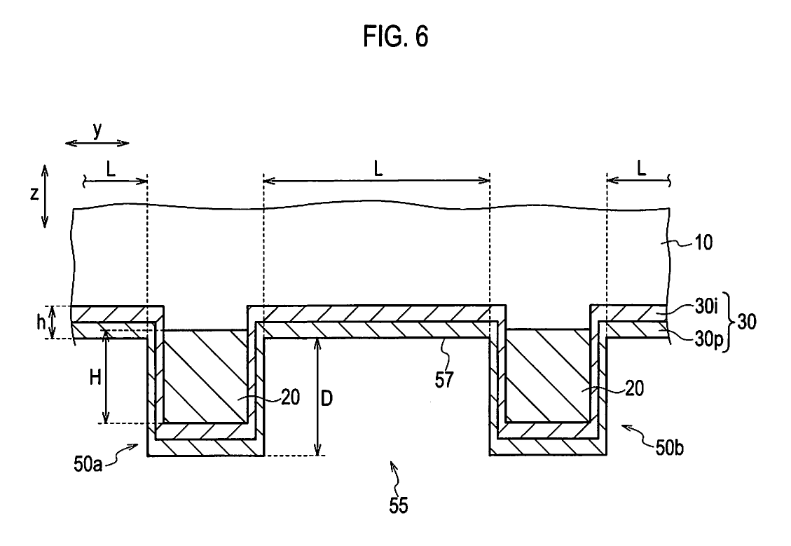

The first semiconductor regions 20 are provided to extend in a first direction x, on the back surface of the semiconductor substrate 10. A longitudinal direction of the first semiconductor regions 20 is the first direction x. A plurality of the first semiconductor regions 20 are provided at predetermined intervals in a second direction y which is orthogonal to the first direction x. The first semiconductor regions 20 are formed in at least surfaces of the respective protruding portions 50 provided on the back surface of the semiconductor substrate 10. As shown in FIG. 2, each first semiconductor region 20 is formed inside a corresponding one of the protruding portions 50. In addition, as shown in FIG. 2, one protruding portion 50a and another protruding portion 50b adjacent to the one protruding portion 50a forma recessed portion 55 (see FIG. 6).

Each first semiconductor region 20 includes a highly concentrated impurity of the same first conductivity type as the semiconductor substrate 10. In the solar cell 1, the conductivity type of the first semiconductor region 20 is an n⁺-type. The first semiconductor region 20 is made of an n⁺-type diffusion layer in which an n-type dopant (phosphorus (P), for example) is introduced into n-type single-crystalline silicon.

The first semiconductor region 20 is in the same crystal state as the semiconductor substrate 10. Since the semiconductor substrate 10 in the embodiment is a single crystal, the first semiconductor region 20 is also a single crystal. The first semiconductor region 20 is a diffusion layer formed by thermal diffusion. Thus, an interface between the first semiconductor region 20 and the semiconductor substrate 10 is formed in a deep area which is about 0.5 μm away from a surface thereof. For this reason, scratches hardly occur on a junction portion between the first semiconductor region 20 and the semiconductor substrate 10.

The second semiconductor layer 30 is formed in the first direction x, on the back surface of the semiconductor substrate 10. The second semiconductor layer 30 is formed on the semiconductor substrate 10 located between the one protruding portion 50a and the other protruding portion 50b. Accordingly, on the semiconductor substrate 10 as shown in FIG. 2, the first semiconductor region 20 and the second semiconductor layer 30 forming a p-n junction with the semiconductor substrate 10 are formed alternately. The direction in which the first semiconductor region 20 and the second semiconductor layer 30 are formed alternately coincides with the second direction y. In the solar cell 1, the first direction x and the second direction y are orthogonal to each other. In addition, the second semiconductor layer 30 serves as a bottom portion 57 of the recessed portion 55.

The second semiconductor layer 30 is of a second conductivity type different from the first conductivity type. In the solar cell 1, the conductivity type of the second semiconductor layer 30 is a p-type.

The second semiconductor layer 30 includes at least a p-type amorphous semiconductor layer 30p. Preferably, a thin-film i-type amorphous semiconductor layer 30i is inserted between the semiconductor substrate 10 and the p-type amorphous semiconductor layer 30p. The i-type amorphous semiconductor layer 30i preferably has a thickness which does not substantially contribute to power generation, for example, the thickness of several Å to 250 Å. The i-type amorphous semiconductor layer 30i and the p-type amorphous semiconductor layer 30p can be formed from an amorphous semiconductor including hydrogen. Examples of the amorphous semiconductor include amorphous silicon, amorphous silicon carbide, amorphous silicon germanium, and the like. The i-type amorphous semiconductor layer 30i is formed without actively introducing impurities into the amorphous semiconductor. The p-type amorphous semiconductor layer 30p is formed by introducing a p-type dopant (boron (B), for example) into the amorphous semiconductor.

The solar cell 1 according to the embodiment has a structure in which the i-type amorphous semiconductor layer 30i and the p-type amorphous semiconductor layer 30p are sequentially formed on the n-type semiconductor substrate 10 (what is called a “HIT” (registered trademark) structure), and therefore the p-n junction characteristics are improved.

As shown in FIG. 2, the first semiconductor region 20 is covered with the second semiconductor layer 30 except for the portion connected with a corresponding one of the electrodes 40n. The second semiconductor layer 30 is also formed on the first semiconductor region 20. In the solar cell 1, the second semiconductor layer 30 includes hydrogen. Accordingly, on the first semiconductor region 20, the second semiconductor layer 30 serves as a passivation layer for preventing recombination of carriers on a crystal surface.

In the solar cell 1 as shown in FIG. 2, the second semiconductor layer 30 is formed directly on the back surface of the semiconductor substrate 10 located between the one protruding portion 50a and the other protruding portion 50b. Each protruding portion 50 is higher than the second semiconductor layer 30 formed on the back surface of the semiconductor substrate 10. For this reason, a physical contact with the second semiconductor layer 30 is prevented by the first semiconductor region 20. Accordingly, scratches can be prevented from occurring on the junction between the second semiconductor layer 30 and the semiconductor substrate 10. In the solar cell 1, the junction between the second semiconductor layer 30 and the semiconductor substrate 10 is a p-n junction. Thus, deterioration of conversion efficiency can be suppressed which would otherwise occur when scratches occur on the junction portion. Note that the height of the protruding portion 50 is the length in a third direction z which is orthogonal to the first direction x and the second direction y.

A depth D of the recessed portion 55 is preferably 0.4 μm or more. With this configuration, scratches can be further prevented from occurring on the junction between the second semiconductor layer 30 and the semiconductor substrate 10. Note that the height of the protruding portion 50 and the depth D of the recessed portion 55 coincide with each other.

An interval L between the one protruding portion 50a and the other protruding portion 50b is preferably 5 mm or less. With this configuration, nothing is likely to enter a space between the one protruding portion 50a and the other protruding portion 50b, and thus scratches can be further prevented from occurring on the junction between the second semiconductor layer 30 and the semiconductor substrate 10.

In the solar cell 1, the height of the protruding portion 50 is preferably five times or more a thickness h of the second semiconductor layer. With this configuration, scratches can be further prevented from occurring on the junction between the second semiconductor layer 30 and the semiconductor substrate 10.

A thickness H of the first semiconductor region 20 is 0.5 μm or more, and the thickness h of the second semiconductor layer is preferably 0.1 μm or less. With this configuration, scratches can be further prevented from occurring on the junction between the second semiconductor layer 30 and the semiconductor substrate 10.

Through the first semiconductor region 20, each electrode 40n collects carriers (electrons) generated in the semiconductor substrate 10. In the embodiment, the electrode 40n includes a connecting layer 41, a barrier layer 43, a foundation layer 45, and a plating layer 47. However, the embodiment is not limited thereto.

The connecting layer 41 is provided to collect photo-generated carriers from the first semiconductor region 20. The connecting layer 41 is formed such that the second semiconductor layer 30 is altered by irradiation of a laser beam, for example, to have low resistance. Alternatively, when a groove is provided in the second semiconductor layer 30 formed on the first semiconductor region 20, the connecting layer 41 is formed from the same material as the barrier layer 43. The second semiconductor layer 30 formed on the first semiconductor region 20 serves as a passivation layer. From a viewpoint of widening the area of the passivation layer, the width of the connecting layer 41 in the second direction y is preferably small. To be specific, the width of the connecting layer 41 is preferably one tenth or less of the width of the protruding portion 50 in the second direction y. Instead of forming the connecting layer 41 in a line shape in the first direction x, the connecting layer 41 may be formed at predetermined intervals in the first direction x.

The barrier layer 43 is provided so that a metal constituting the foundation layer 45 can be prevented from diffusing into the second semiconductor layer 30 formed on the first semiconductor region 20. Titanium (Ti) is used for the barrier layer 43, for example. A transparent electrode (TCO) may be used for the barrier layer 43.

The foundation layer 45 is provided as a foundation to form the plating layer 47. Cu, Cu alloy, Ag, or Ni is used for the foundation layer 45, for example.

The plating layer 47 is provided to reduce resistance loss of the electrode 40n. The plating layer 47 may be formed to be multi-layered. With this formation, the electrode 40n can be handled easily. The same material as the foundation layer 45 is used for the plating layer 47, for example. When the plating layer 47 is formed to be multi-layered, a plurality of materials may be selected from the same materials used for the foundation layer 45.

Through the second semiconductor layer 30, each electrode 40p collects photo-generated carriers (holes) generated in the semiconductor substrate 10. In the embodiment, the electrode 40p includes the barrier layer 43, the foundation layer 45, and the plating layer 47. However, the embodiment is not limited thereto. The configurations of the barrier layer 43, the foundation layer 95, and the plating layer 47 are the same as those of the electrode 40n.

The collector electrode 70n further collects photo-generated carriers (electrons) collected in the plurality of electrodes 40n. As shown in FIG. 1, the collector electrode 70n is connected to end portions of the electrodes 40n. The collector electrode 70p further collects carriers (holes) collected in the plurality of electrodes 40p. As shown in FIG. 1, the collector electrode 70p is connected to end portions of the electrodes 40p. The solar cell 1 employs a connecting method in which the collector electrode 70n and the collector electrode 70p are provided one each. However, the solar cell 1 may employ a connecting method in which a plurality of the collector electrodes 70n and the collector electrodes 70p are provided.

(2) Method for Manufacturing Solar Cell 1

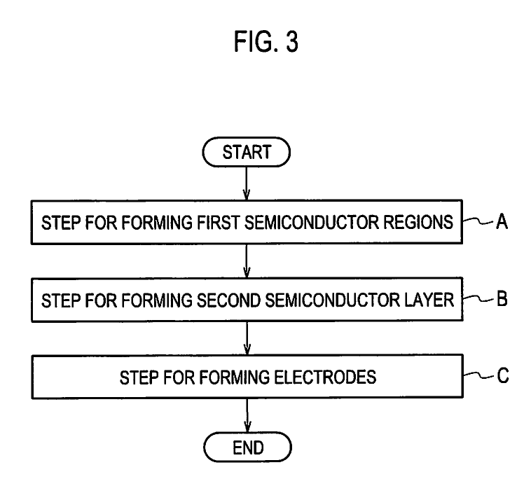

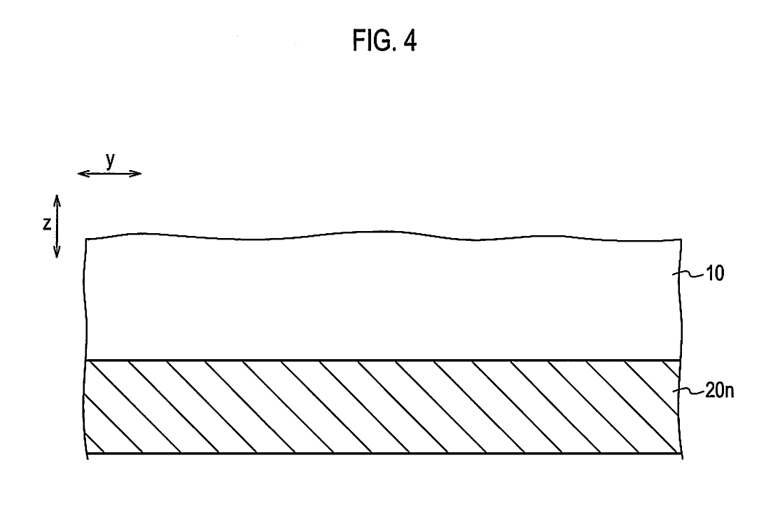

Description will be given of a method for manufacturing the solar cell 1 with reference to FIG. 3 to FIG. 8. FIG. 3 is a flowchart for explaining the method for manufacturing the solar cell 1 according to the embodiment of the present invention. FIG. 4 to FIG. 8 are diagrams for explaining the method for manufacturing the solar cell 1 according to the embodiment of the present invention.

As shown in FIG. 3, the method for manufacturing the solar cell 1 includes Step S1 to Step S3.

Step S1 is a step of forming the first semiconductor regions 20 of the first conductivity type, on a back surface side of the semiconductor substrate 10. First of all, the semiconductor substrate 10 is prepared. The semiconductor substrate 10 is an n-type single-crystalline silicon substrate. Etching with acid or alkaline solution has been performed on the semiconductor substrate 10 to remove dirt on a surface of the semiconductor substrate 10. The prepared semiconductor substrate 10 is heated in an atmosphere containing n-type impurities to introduce the n-type impurities into the surface of the semiconductor substrate 10. Thereby, the first semiconductor region 20 is formed in the surface of the semiconductor substrate 10, as shown in FIG. 4. The first semiconductor region 20 is a diffusion layer of an n⁺-type conductivity type. For this reason, the first semiconductor region 20 is in the same crystal state as the semiconductor substrate 10. The first semiconductor region 20 is preferably formed to have the thickness H of 0.5 μm or more.

Step S2 is a step of forming the second semiconductor layer 30 of a second conductivity type, on the back surface of the semiconductor substrate 10. Step S2 includes Step S21 and Step S22.

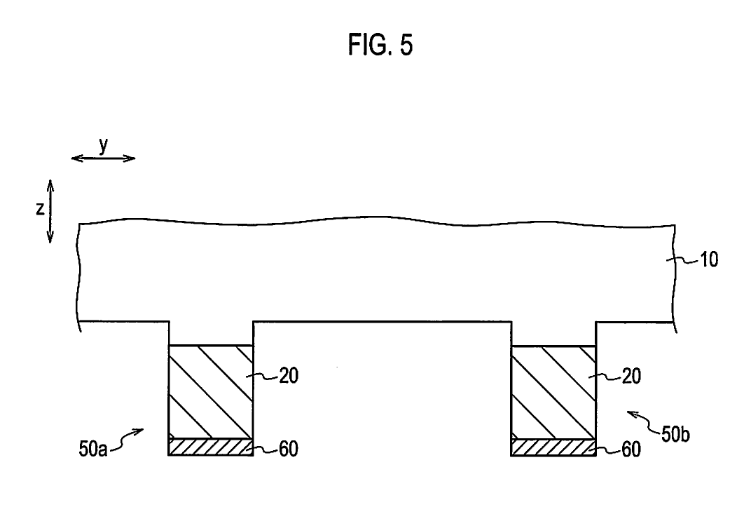

Step S21 is a step of removing the first semiconductor region 20 at intervals. First of all, as shown in FIG. 5, a resist 60 for protecting the first semiconductor region 20 is applied to the first semiconductor region 20 by screen printing, for example. Portions of the first semiconductor region 20 to which the resist 60 is applied become the first semiconductor regions 20 in the solar cell 1. For this reason, the resist 60 is applied to the first semiconductor region 20 at intervals in the second direction y. These intervals substantially determine the interval L. Accordingly, the resist 60 is preferably applied so that the interval L can be 5 mm or less. A material having resistance against etching liquid for etching the first semiconductor region 20 is used for the resist 60.

Next, the first semiconductor region 20 is removed by etching. Hydrofluoric acid and nitric acid mixture is used as the etching liquid for removing the first semiconductor region 20, for example. As shown in FIG. 5, the first semiconductor region 20 is removed at intervals by etching. The portions of the first semiconductor region 20 to which the resist 60 is applied remain, while the portions to which the resist 60 is not applied are removed. Thereby, a surface of the semiconductor substrate 10 is exposed. In addition, a plurality of protruding portions having the first semiconductor regions 20 in their surfaces are formed. In the solar cell 1, not only the first semiconductor region 20 but also part of the semiconductor substrate 10 is removed to make the first semiconductor region 20 protrude. Additionally, as shown in FIG. 4, the plurality of protruding portions which are not removed but remain form the one protruding portion 50a and the other protruding portion 50b adjacent to the one protruding portion 50a. The heights of the one protruding portion 50a and the other protruding portion 50b excluding the resist 60 are substantially the depth D of the recessed portion 55. For this reason, the first semiconductor region 20 and the semiconductor substrate 10 are preferably removed so that the heights of the one protruding portion 50a and the other protruding portion 50b can be 0.4 μm or more. Subsequently, the resist 60 is peeled off with alkaline solution (NaOH, for example). The semiconductor substrate 10 is cleaned with cleaning liquid (SC-2 solution and HF, for example).

Step S22 is a step of forming the second semiconductor layer 30 on the surface of the semiconductor substrate 10 which is exposed by removal of the first semiconductor region 20. By using CVD, the i-type amorphous semiconductor layer 30i is formed on the surface of the semiconductor substrate 10 which is exposed by removal of the first semiconductor region 20. Moreover, the p-type amorphous semiconductor layer 30p is formed on the i-type amorphous semiconductor layer 30i. Thereby, the second semiconductor layer 30 forms the bottom portion 57 of the recessed portion 55 formed by the one protruding portion 50a and the other protruding portion 50b. Since the second semiconductor layer 30 is the bottom portion 57 of the recessed portion 55, the height of the protruding portion 50 needs to be larger than the second semiconductor layer 30 formed on the semiconductor substrate 10. Hence, the second semiconductor layer 30 is preferably formed so that the thickness h of the second semiconductor layer 30 can be one fifth or less of the height of the protruding portion 50. In addition, the thickness h of the second semiconductor layer 30 is preferably 0.1 μm or less.

An example of a method of forming the i-type amorphous semiconductor layer 30i and the p-type amorphous semiconductor layer 30p includes chemical vapor deposition (CVD) such as plasma chemical vapor deposition. As shown in FIG. 6 in the step S22, while the second semiconductor layer 30 is formed on the semiconductor substrate 10, the second semiconductor layer 30 may be formed on the first semiconductor regions 20, i.e. on the protruding portions as well. In other words, the second semiconductor layer 30 may be formed on substantially the entire surface of the semiconductor substrate 10 on the back surface side. Thereby, the manufacturing step can be simplified. In the solar cell 1, the first semiconductor regions 20 are covered with the second semiconductor layer 30.

Step S3 is a step of forming the electrodes 40n and the electrodes 40p. First of all, the connecting layer 41 is formed by altering the second semiconductor layer 30 on the first semiconductor region 20, or by removing the second semiconductor layer 30. An example of a method of altering the second semiconductor layer 30 includes a method using a laser. Carriers are outputted to an external circuit through the portions of the altered second semiconductor layer 30, i.e. the connecting layer 41. An example of a method of removing the second semiconductor layer 30 includes a method using a laser as well. Degrees of alteration or degrees of removal change depending on wavelength, power and the like of the laser. Other examples include: a method of removing part of the second semiconductor layer 30 formed on the first semiconductor regions 20 by etching, with use of etching paste or resist; and a method of mechanically grinding part of the second semiconductor layer 30 formed on the first semiconductor regions 20. Thereby, grooves having the first semiconductor regions 20 as their bottom surfaces are formed. In this case, when the barrier layer 43 is formed, a material constituting the barrier layer 43 enters the grooves. In other words, the connecting layer 41 and the barrier layer 43 are formed together by the same material.

In the solar cell 1, the second semiconductor layer 30 formed on the first semiconductor regions 20 as well serves as a passivation layer. For this reason, the width of the connecting layer 41 is preferably small. To be specific, the width of the connecting layer 41 is preferably one tenth or less of the width of the protruding portion 50 in the second direction y.

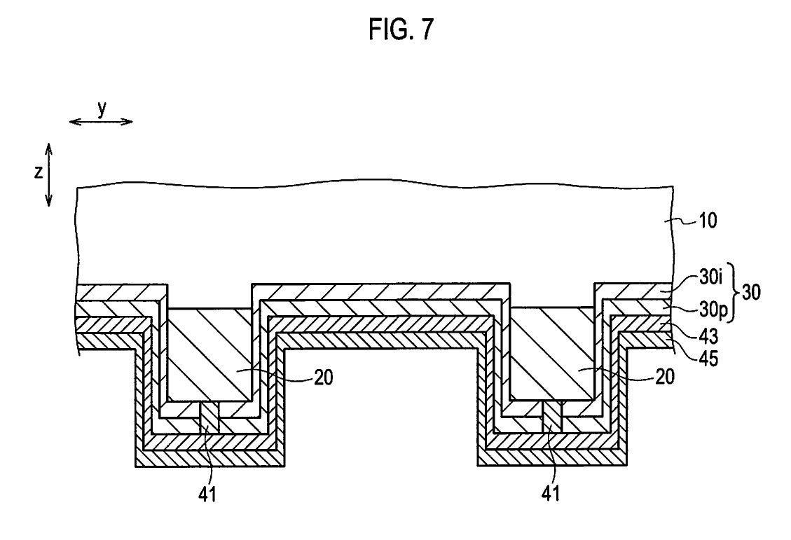

Next, as shown in FIG. 7, the barrier layer 43 and the foundation layer 45 are sequentially formed. The barrier layer 43 is formed on the second semiconductor layer 30. The foundation layer 45 is formed on the barrier layer 43 thus formed. The barrier layer 43 and the foundation layer 45 are formed by sputtering, for example.

Subsequently, the resist 60 is applied to the foundation layer 45 by screen printing. The foundation layer 45 to which the resist 60 is applied becomes part of the electrodes 40n and the electrodes 40p. For this reason, the resist 60 is applied to positions where the electrodes 40n and the electrodes 40p are to be formed. A material having resistance against etching liquid for etching the barrier layer 43 and the foundation layer 45 is used for the resist 60.

In a conventional solar cell, a screen pushed by a squeegee may come into contact with a semiconductor layer, in applying the resist 60. When a thin semiconductor layer and a semiconductor substrate are joined together, such a contact may cause scratches on their junction portion. In contrast, according to the solar cell 1 of the embodiment, the thin second semiconductor layer 30 is formed between the one protruding portion 50a and the other protruding portion 50b adjacent to the one protruding portion 50a. For this reason, in printing the resist 60, a screen is less likely to come into contact with the second semiconductor layer 30 because the one protruding portion 50a and the other protruding portion 50b block the screen. As a result, scratches can be prevented from occurring on the junction portion between the second semiconductor layer 30 and the semiconductor substrate 10.

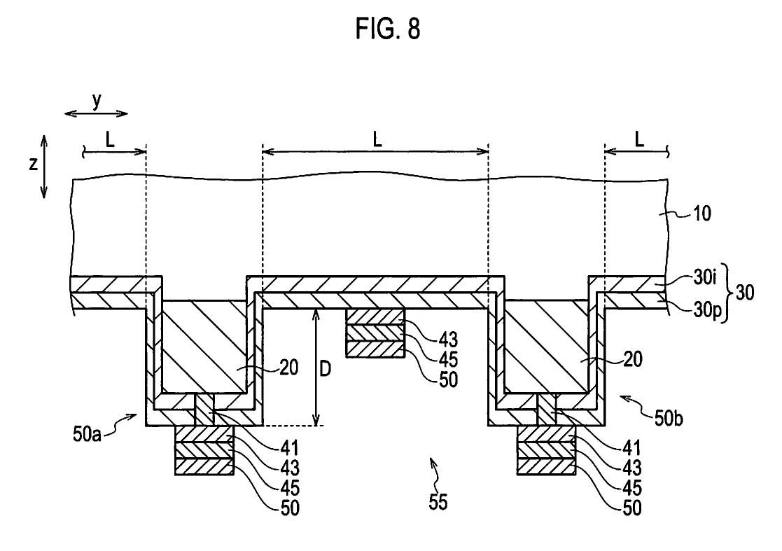

Next, the barrier layer 43 and the foundation layer 45 are removed by etching. In order to remove the barrier layer 43 and the foundation layer 45, ferric chloride and hydrofluosilicic acid are used for etching liquid, for example. As shown in FIG. 8, by etching, the portions to which the resist 60 is applied remain, while the barrier layer 43 and the foundation layer 45 to which the resist 60 is not applied are removed. The resist 60 applied to the foundation layer 45 is removed by NaOH solution, for example. Thereafter, the plating layer 47 is formed on the foundation layer 45. The plating layer 47 is formed by performing electrolytic plating. Thereby, the solar cell 1 as shown in FIG. 2 is formed.

(3) Operation and Effect

In the solar cell 1, the plurality of protruding portions 50 are formed on the back surface of the semiconductor substrate 10. The second semiconductor layer 30 is formed on the semiconductor substrate 10 located between the one protruding portion 50a and the other protruding portion 50b adjacent to the one protruding portion 50a. The recessed portions 55 having the second semiconductor layer 30 as the bottom portions 57 thereof are each formed by the one protruding portion 50a and the other protruding portion 50b. For this reason, in printing the resist 60, a metal mask or a screen is less likely to come into contact with the second semiconductor layer 30 because the one protruding portion 50a and the other protruding portion 50b block the metal mask or the screen. As a result, scratches can be prevented from occurring on the junction portion between the second semiconductor layer 30 and the semiconductor substrate 10. Not only the metal mask or the screen but also another physical contact in handling of the solar cell 1 can be prevented. The first semiconductor regions 20 are formed in the protruding portions 50. Moreover, the first semiconductor regions 20 are in the same crystal state as the semiconductor substrate 10, and their junction is located at a portion deeper than a surface thereof. For this reason, scratches hardly occur on the junction portions between the semiconductor substrate 10 and the first semiconductor regions 20.

In the solar cell 1, the depth D of each recessed portion 55 is 0.4 μm or more. In addition, the interval L between the one protruding portion 50a and the other protruding portion 50b is 5 mm or less. For this reason, the one protruding portion 50a and the other protruding portion 50b are likely to block an external physical contact with the second semiconductor layer 30. Scratches can be further prevented from occurring on the junction between the second semiconductor layer 30 and the semiconductor substrate 10.

In the solar cell 1, the semiconductor substrate 10 is of the first conductivity type. For this reason, the semiconductor substrate 10 and the second semiconductor layer 30 are of different conductivity types from each other. Accordingly, the junction between the semiconductor substrate 10 and the second semiconductor layer 30 is a p-n junction. Deterioration of conversion efficiency can be suppressed which would otherwise occur when scratches occur on the junction portion between the semiconductor substrate 10 and the second semiconductor layer 30.

In the solar cell 1, the second semiconductor layer 30 is formed on the first semiconductor regions 20 as well. The second semiconductor layer 30 on the first semiconductor regions 20 serves as a passivation layer. Hence, recombination of carriers can be prevented.

In the method for manufacturing the solar cell 1, Step S1 includes a step in which the semiconductor substrate 10 is heated to introduce impurities into the semiconductor substrate 10 whereby the first semiconductor regions 20 are formed in the surface of the semiconductor substrate 10. Step S2 includes Step S21 in which the semiconductor substrate 10 is exposed by removing the first semiconductor region 20 at intervals, and Step S22 in which the second semiconductor layer 30 is formed on the semiconductor substrate 10 exposed by removal of the first semiconductor region 20. The first semiconductor regions 20 are formed in the plurality of protruding portions 50 which are not removed but remain. The bottom portion 57 of each recessed portion 55 formed by the one protruding portion 50a and the other protruding portion 50b adjacent to the one protruding portion 50a is the second semiconductor layer 30. Thereby, the solar cell 1 can be manufactured.

In the method for manufacturing the solar cell 1, in Step S22, while the second semiconductor layer 30 is formed on the semiconductor substrate 10, the second semiconductor layer 30 is formed on the first semiconductor regions 20 as well. Thereby, the step of manufacturing the solar cell 1 can be simplified.

(4) Other Embodiments

As described above, the details of the present invention have been disclosed by using the embodiment of the present invention. However, it should not be understood that the description and drawings which constitute part of this disclosure limit the present invention.

In the embodiment of the present invention, the semiconductor substrate 10 is an n-type, the first semiconductor region 20 is an n⁺-type, and the second semiconductor layer 30 is a p-type. However, the embodiment is not limited thereto. For example, the semiconductor substrate 10 maybe an n-type, the first semiconductor regions 20 may be a p-type, and the second semiconductor layer 30 may be an n-type. In this case, scratches can be prevented from occurring on the junction portion between the semiconductor substrate 10 and the second semiconductor layer 30 serving as a BSF layer provided to prevent recombination of carriers on the back surface.

In addition, the semiconductor substrate 10 may be a p-type, the first semiconductor regions 20 may be a p⁺-type, and the second semiconductor layer 30 may be an n-type. In this case, as in the case of the solar cell 1, scratches can be prevented from occurring on a p-n junction portion which is the junction between the second semiconductor layer 30 and the semiconductor substrate 10. As in the case of the solar cell 1, the second semiconductor layer 30 maybe formed on the first semiconductor regions 20 as well. The second semiconductor layer 30 on the first semiconductor regions 20 serves as a passivation layer. Thereby, recombination of carriers can be prevented.

In addition, the semiconductor substrate 10 may be a p-type, the first semiconductor region 20 may be an n-type, and the second semiconductor layer 30 may be a p-type. In this case, scratches can be prevented from occurring on the junction portion between the semiconductor substrate 10 and the second semiconductor layer 30 serving as a BSF layer provided to prevent recombination of carriers on the back surface.

Moreover, although the semiconductor substrate 10 is made of single-crystalline silicon, the embodiment is not limited thereto. The semiconductor substrate 10 may be made of polycrystalline silicon.

Furthermore, although the second semiconductor layer 30 is formed of the i-type amorphous semiconductor layer 30i and the p-type amorphous semiconductor layer 30p, the i-type amorphous semiconductor layer 30i is not always necessary. In other words, the second semiconductor layer 30 may be formed of the p-type amorphous semiconductor layer 30p.

As described above, the present invention includes various embodiments which are not described herein. Accordingly, the technical scope of the present invention should be determined only by the matters to define the invention in the scope of claims regarded as appropriate based on the description.

### EXPLANATION OF THE REFERENCE NUMERALS

1 solar cell
10 semiconductor substrate
12 back surface
20 first semiconductor region
30 second semiconductor layer
30i i-type amorphous semiconductor layer
30p p-type amorphous semiconductor layer
40n n-type electrode
40p p-type electrode
41 connecting layer
43 barrier layer
45 foundation layer
47 plating layer
50, 50a, 50b protruding portion
55 recessed portion
57 bottom portion
60 resist
70n, 70p collector electrode

1. A solar cell comprising a semiconductor substrate having a light receiving surface and a back surface, a first semiconductor region of a first conductivity type and a second semiconductor layer of a second conductivity type, both being disposed on the back surface of the semiconductor substrate, wherein
the semiconductor substrate includes a plurality of protruding portions on the back surface,
the first semiconductor region is provided in a surface of each of the protruding portions,
the second semiconductor layer is provided on the semiconductor substrate located between one protruding portion and another protruding portion adjacent to the one protruding portion among the plurality of protruding portions, and
the one protruding portion and the other protruding portion constitute a recessed portion whose bottom portion is formed by the second semiconductor layer.

2. The solar cell according to claim 1, wherein the depth of the recessed portion is 0.4 μm or more.

3. The solar cell according to claim 1, wherein an interval between the one protruding portion and the other protruding portion adjacent to the one protruding portion is 5 mm or less.

4. The solar cell according to claim 1, wherein the semiconductor substrate is of the first conductivity type.

5. The solar cell according to claim 1, wherein the semiconductor substrate is of the a second conductivity type.

6. The solar cell according to claim 1, wherein the second semiconductor layer is formed on the first semiconductor region as well.

7. The solar cell according to claim 1, wherein the solar cell includes an electrode electrically connected to the first semiconductor region, and an electrode electrically connected to the second semiconductor layer.

8. The solar cell according to claim 1, wherein the semiconductor substrate includes texture on the light receiving surface.

9. The solar cell according to claim 1, wherein the solar cell includes a passivation layer provided on the light receiving surface of the semiconductor substrate.

10. The solar cell according to claim 1, wherein the solar cell includes an antireflection film provided on the light receiving surface of the semiconductor substrate.

11. The solar cell according to claim 1, wherein no structure that blocks the entrance of light is provided on the light receiving surface of the semiconductor substrate.

12. The solar cell according to claim 1, wherein the light receiving surface of the semiconductor substrate is capable of receiving light with the entire surface thereof.

13. The solar cell according to claim 1, wherein the semiconductor substrate is made of crystalline silicon.

14. The solar cell according to claim 1, wherein the first semiconductor region is formed from the same material as the semiconductor substrate.

15. The solar cell according to claim 1, wherein the second semiconductor layer is formed from an amorphous semiconductor.

16. The solar cell according to claim 1, wherein the second semiconductor layer is formed from amorphous silicon.

17. The solar cell according to claim 15, wherein the second semiconductor layer includes hydrogen.

18. A solar cell manufacturing method for manufacturing a solar cell comprising a semiconductor substrate having a light receiving surface and a back surface, a first semiconductor region of a first conductivity type and a second semiconductor layer of a second conductivity type, both being disposed on the back surface of the semiconductor substrate, wherein
the method comprises:
a step S1 of forming the first semiconductor region of the first conductivity type on the back surface of the semiconductor substrate having the light receiving surface and the back surface; and
a step S2 of forming the second semiconductor layer of the second conductivity type on the back surface,
the step S1 includes a step of forming the first semiconductor region in a surface of the semiconductor substrate by heating the semiconductor substrate and introducing impurities into the semiconductor substrate,
the step S2 includes: a step S21 of exposing part of the semiconductor substrate by removing the first semiconductor region at intervals; and a step S22 of forming the second semiconductor layer on the semiconductor substrate which is exposed by the removal of the first semiconductor region,
the first semiconductor region is formed in at least a surface of each of a plurality of protruding portions which are not removed but remain, and
the second semiconductor layer forms a bottom portion of a recessed portion formed by one protruding portion and another protruding portion adjacent to the one protruding portion among the plurality of protruding portions.

19. The solar cell manufacturing method according to claim 18, wherein
in the step S22, the second semiconductor layer is formed on the semiconductor substrate and is also formed on the first semiconductor region.

20. The solar cell according to claim 2, wherein an interval between the one protruding portion and the other protruding portion adjacent to the one protruding portion is 5 mm or less.

21. The solar cell according to claim 16, wherein the second semiconductor layer includes hydrogen.
